(19) United States
(12) Patent Application Publication
(10) Pub. No.: US 2013/0321708 A1
(43) Pub. Date: Dec. 5, 2013

(54) TELEVISION RECEIVER AND ELECTRONIC DEVICE

(71) Applicant: KABUSHIKI KAISHA TOSHIBA, Tokyo (JP)

(72) Inventor: Takuo Matsumoto, Hamura-shi (JP)

(73) Assignee: KABUSHIKI KAISHA TOSHIBA, Tokyo (JP)

(21) Appl. No.: 13/771,490

(22) Filed: Feb. 20, 2013

(30) Foreign Application Priority Data
May 30, 2012 (JP) 2012-123579

(51) Int. Cl. H05K 5/00; H04N 5/44

(52) U.S. Cl. CPC H05K 5/00; H04N 5/44
USPC 348/725; 361/749

(57) ABSTRACT

According to one embodiment, a television receiver includes: a housing; a display device; a cable; and a flexible printed wiring board. The display device includes a display screen. At least a portion of the display device is housed in the housing. The cable is housed in the housing. The flexible printed wiring board is housed in the housing. At least a portion of the flexible printed wiring board is provided to position along or to overlap with the cable. The flexible printed wiring board includes a wiring area and a projecting portion configured to project from the wiring area and to overlap with the cable.

### CROSS-REFERENCE TO RELATED APPLICATIONS

This application is based upon and claims the benefit of priority from Japanese Patent Application No. 2012-123579, filed May 30, 2012, the entire contents of which are incorporated herein by reference.

### FIELD

Embodiments described herein relate generally to a television receiver and an electronic device.

### BACKGROUND

Conventionally, there is known an electronic device comprising a flexible printed wiring board housed in a housing thereof.

In such electronic device housing the flexible printed wiring board, it is unfavorable that inconveniences such that the flexible printed wiring board is rubbed against other cables occur.

### BRIEF DESCRIPTION OF THE DRAWINGS

A general architecture that implements the various features of the invention will now be described with reference to the drawings. The drawings and the associated descriptions are provided to illustrate embodiments of the invention and not to limit the scope of the invention.

FIG. 1 is an exemplary perspective view of a television receiver as viewed from a frontal side thereof, according to a first embodiment;

FIG. 2 is an exemplary side view of the television receiver in the first embodiment;

FIG. 3 is an exemplary back view illustrating an example of an internal structure of the television receiver (a view of the television receiver from which a housing member on a back side thereof is removed), in the first embodiment;

FIG. 4 is an exemplary view schematically illustrating a flexible printed wiring board and a flat cable comprised in the television receiver in the first embodiment;

FIG. 5 is an exemplary cross-sectional view taken along the line V-V in FIG. 4, including circuit boards, in the first embodiment;

FIG. 6 is an exemplary perspective view of an electronic device according to a second embodiment;

FIG. 7 is an exemplary plan view illustrating an example of an internal structure of a second housing of the electronic device (a bottom view of the electronic device from which a housing member on a lower side thereof is removed), in the second embodiment;

FIG. 8 is an exemplary plan view of a flexible printed wiring board and a flat cable according to a first modification;

FIG. 9 is an exemplary plan view of a flexible printed wiring board and a flat cable according to a second modification;

FIG. 10 is an exemplary plan view of a flexible printed wiring board and a flat cable according to a third modification;

FIG. 11 is an exemplary plan view of a flexible printed wiring board and a flat cable according to a fourth modification;

FIG. 12 is an exemplary plan view of a flexible printed wiring board, a flat cable, and an electrical component according to a fifth modification; and

FIG. 13 is an exemplary cross-sectional view taken along the line XIII-XIII in FIG. 12 in the fifth modification.

### DETAILED DESCRIPTION

In general, according to one embodiment, a television receiver includes: a housing; a display device; a cable; and a flexible printed wiring board. The display device comprises a display screen. At least a portion of the display device is housed in the housing. The cable is housed in the housing. The flexible printed wiring board is housed in the housing. At least a portion of the flexible printed wiring board is provided to position along or to overlap with the cable. The flexible printed wiring board comprises a wiring area and a projecting portion configured to project from the wiring area and to overlap with the cable.

Exemplary embodiments and modifications in the following comprise the same or similar configuration elements. Accordingly, in the following description, the same or similar configuration elements are given with common reference numerals or symbols, and redundant explanations are omitted.

While the following embodiments and modifications describe examples in which an electronic device is configured as a television receiver or a notebook type (clamshell type or folding type) personal computer, the electronic device according to the present embodiments is not restricted to these. The electronic device in the embodiments can be configured as an electronic device that comprises a flexible printed wiring board (a flat cable), more specifically, for example, a desktop type or tablet (slate) type personal computer, a smart television, a video display device, a receiver, a video display controller, a projector, and a cellular phone.

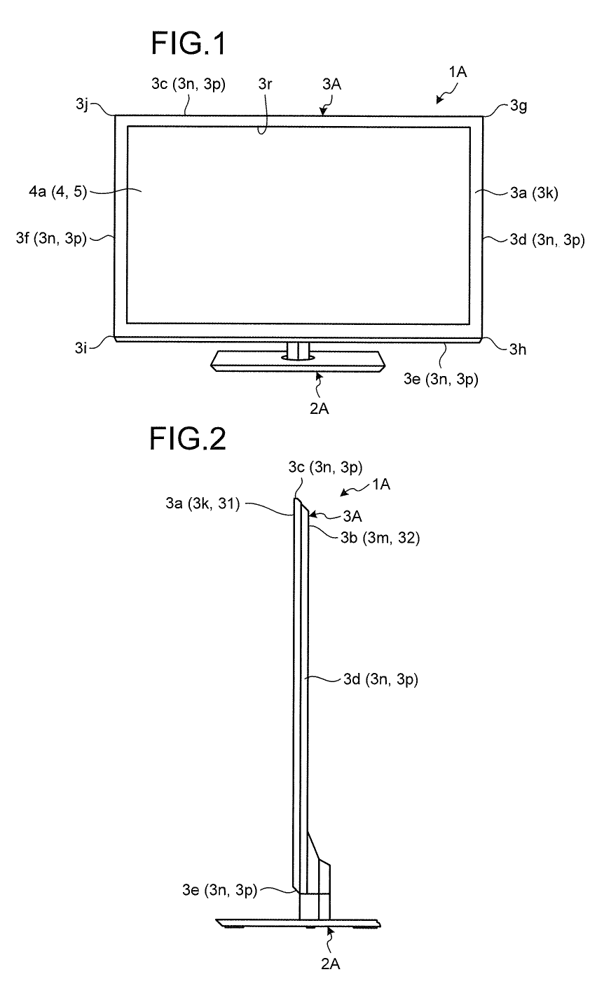

In a first embodiment, as illustrated in FIGS. 1 and 2 as one example, a television receiver 1A (an electronic device) comprises a supporting portion 2A and a housing 3A. Specifically, the housing 3A houses therein at least a portion of a display device 4. The supporting portion 2A (a stand portion, a pedestal portion, or a leg portion) supports the housing 3A. The supporting portion 2A can support the housing 3A to be movable (rotatable). Examples of the movement of the housing 3A in this case include tilting, pivoting, and swiveling.

The housing 3A, in the first embodiment, as illustrated in FIG. 1 as one example, is constructed in a quadrangular shape (in the first embodiment, a rectangular shape as one example) in a frontal view and in a back view. Furthermore, the housing 3A, in the first embodiment, as illustrated in FIG. 2 as one example, is constructed in a rectangular parallelepiped shape to be thin and flat in a front-back direction. The housing 3A comprises a surface 3a (an anterior surface, a top surface, a front face, or a surface portion), and on a side opposite the surface 3a, a surface 3b (a rear surface, a lower surface, a back surface, or a surface portion). Both the surface 3a and the surface 3b extend (expand) along a direction intersecting a thickness direction of the housing 3A (in the first embodiment, in an orthogonal direction as one example). The surface 3a and the surface 3b are nearly in parallel with each other. The housing 3A further comprises, as illustrated in FIG. 1, four ends 3c to 3f (sides, or edges) and four corners 3g to 3j (protruding portions, rounded portions, or ends) in a frontal view. The ends 3c and 3e are examples of longer sides. The ends 3d and 3f are examples of shorter sides.

The housing 3A further comprises, as one example, a wall 3k (a part, a plate, a frame, a front wall, a surface wall, or a top wall) having the surface 3a, and a wall 3m (a part, a plate, a rear wall, a back wall, or a bottom wall) having the surface 3b. The walls 3k and 3m are in a quadrangular shape (in the first embodiment, a rectangular shape as one example). The housing 3A further comprises four walls 3n (parts, plates, side walls, end walls, standing walls, or extending portions) having surfaces 3p (side surfaces, or circumferential surfaces) extending between the wall 3k and the wall 3m. On the wall 3k, an opening 3r in a quadrangular shape as one example is provided. Therefore, the wall 3k is in a quadrangular and frame-like shape.

Furthermore, the housing 3A can be constructed with a plurality of components (segmented bodies) combined. The housing 3A, in the first embodiment, as one example, comprises a housing member 31 (a front side member, a mask, a mask portion, a cover, a front cover, a cover portion, a portion, or an area) having at least the wall 3k, and the housing member 32 (a back side member, a base, a base portion, a bottom, a bottom portion, a cover, a rear cover, a cover portion, a portion, or an area) having at least the wall 3m. The walls 3n are comprised in at least one of the housing member 31 and the housing member 32 (for example, the housing member 32). Moreover, the housing 3A can comprise another housing member (an intermediate member, an isolating member, a barrier wall member, a wall member, an intervening member, a covering member, an inner plate, a middle plate, a middle frame, a shield, a portion, or an area, not illustrated) positioned between the housing member 31 and the housing member 32. The housing 3A can be composed of metallic or synthetic resin material. On the inner sides of the housing member 31 and the housing member 32 of the housing 3A, walls (projecting portions, or projecting walls, not illustrated) such as ribs can be provided. These walls facilitate an increase in the rigidity of the housing 3A.

In the first embodiment, on the surfaces 3a, 3b, and 3p of the housing 3A, as one example, connectors, operation modules, a camera module (a camera, or an imaging device), and others (not illustrated) can be provided. The connectors can be, for example, a connector for a power supply cable, a universal serial bus (USB) connector, a card connector, and connectors for earphones and a microphone. The operation modules can be, for example, a push button, a push switch, a slide switch, a pointing device, and a dial.

In the first embodiment, as illustrated in FIG. 1 as one example, a display screen 4a of the display device 4 (a display module, a display, or a panel) positioned on the surface 3a side is visible from the front (outside) of the housing 3A through the opening 3r. The display device 4 is configured in a quadrangular shape (in the first embodiment, a rectangular shape as one example) in a frontal view. The display device 4 is further configured in a rectangular parallelepiped shape to be thin and flat in the front-back direction. The display device 4, for example, is a liquid crystal display (LCD) or an organic electro-luminescent display (OELD).

In the first embodiment, on the front side (a face side, or the wall 3k side) of the display device 4, as one example, a touch panel 5 (as one example, an input operation panel, a touch sensor, an operation surface, or a cover) can be provided. In this case, the touch panel 5 is configured in a transparent and relatively thin quadrangular shape, covering the display screen 4a. A user, for example, can execute input process by performing an operation of touching, pressing, or rubbing the touch panel 5 with a finger or a component (for example, a stylus, not illustrated), or moving the finger or the stylus near the touch panel 5. The light emitted from the display screen 4a of the display device 4 passes through the touch panel 5 and goes out ahead (outside) of the housing 3A through the opening 3r of the wall 3k.

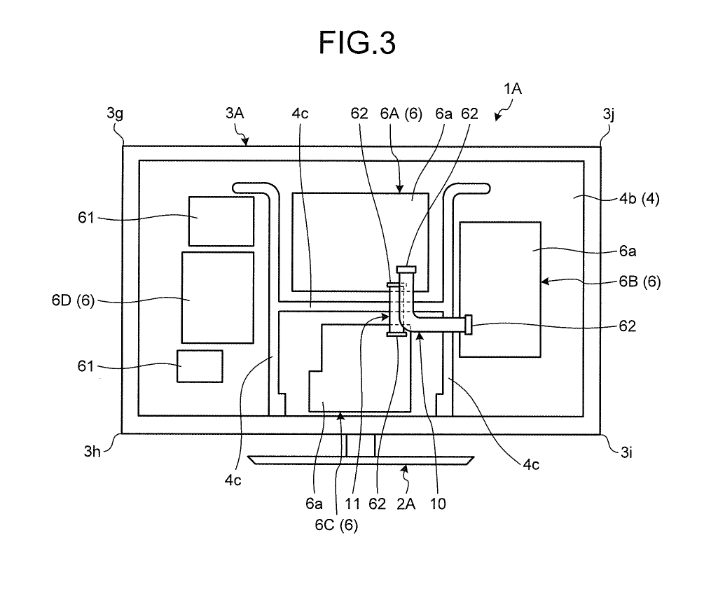

In the first embodiment, as one example, as illustrated in FIG. 3, one or more substrates 6 (a circuit board, a control board, a main board, electrical components, or components) are housed on the rear side (a reverse side, a back side, the wall 3m side, or the side opposite the display screen 4a) of the display device 4 inside the housing 3A. The substrates 6 are provided roughly in parallel with the display device 4. The substrates 6 are provided in a condition to be away from the walls 3k, 3m, 3n, and others, in other words, in a condition where spaces (gaps) are formed with the walls 3k, 3m, 3n, and others.

In the first embodiment, on the substrates 6, as one example, a plurality of components (not illustrated), for example, a central processing unit (CPU), a graphics controller, power supply circuit components, a platform controller hub (PCH), a memory slot connector, an LCD connector, an input/output (I/O) connector, a power coil, elements, and connectors can be mounted. Furthermore, the control circuit can comprise, for example, a video signal processing circuit, a tuner, a High-Definition Multimedia Interface (HDMI) signal processor, an audio video (A/V) input terminal, a remote control signal receiver, a controller, a selector, an on-screen display interface, a storage module (for example, a read only memory (ROM), a random access memory (RAM), a hard disk drive (HDD), and a solid state drive (SSD)), and an audio signal processing circuit. The control circuit controls such as the output of videos (such as movies or still pictures) on the display screen 4a of the display device 4, the output of audio from a speaker (not illustrated), and light emission of a light emitting diode (LED, not illustrated). The display device 4, the speaker, and the LED are examples of output modules.

As illustrated in FIG. 3, in the first embodiment, as one example, the housing 3A houses therein four pieces of the substrates 6 (6A to 6D). In the first embodiment, as one example, the substrate 6A (a conductor portion thereof) and the substrate 6B (a conductor portion thereof) are electrically connected via a flexible printed wiring board 10 (hereinafter, referred to as an FPC 10), and the substrate 6A (a conductor portion thereof) and the substrate 6C (a conductor portion thereof) are electrically connected via a flexible flat cable 11 (hereinafter, referred to as an FFC 11). The housing 3A further houses therein, other than the substrates 6, electrical components 61 (for example, a power supply circuit unit, a hard disc drive (HDD), a solid state drive (SSD), an optical disk drive (ODD), a battery, and a board). The substrates 6, the FPC 10, and the FFC 11 are examples of electrical components. The FPC 10 and the FFC 11 are both examples of flat cables, flexible cables, or cables.

On a rear surface 4b (a surface, or a back surface) of the display device 4, a rib 4c (a projecting portion, a jutting portion, or a wall) in an H-shape when viewed in a back view is provided. The rib 4c serves as a reinforcing portion of the display device 4. The substrates 6A to 6D are arranged in the respective areas divided by the rib 4c on the rear surface 4b of the display device 4, and are separated from one another. The FPC 10 and the FFC 11 straddle the rib 4c and connect among the substrates 6. On surfaces 6a (reverse surfaces, rear surfaces, back surfaces, or surface portions) of the substrates 6, connectors 62 are provided. The FPC 10 and the FFC 11 are detachably coupled (connected) to the connectors 62.

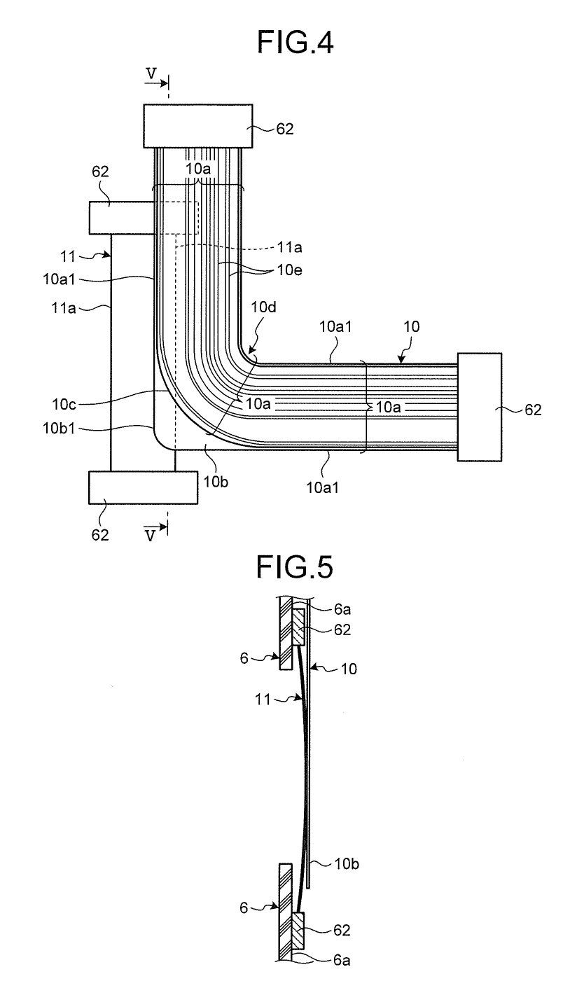

In the first embodiment, as one example, the FPC 10 is configured in a thin film-like and belt-like shape. Specifically, the FPC 10 comprises abase layer (not illustrated), wiring layers 10e, and a cover layer (not illustrated). The base layer is an insulator (for example, synthetic resin material such as polyimide) and is configured in a thin film-like (sheet-like) shape. The wiring layers 10e in plurality and in parallel (conductor patterns) are composed of conductors (for example, metallic material such as copper foil), and are provided on the surface of the base layer on one side. The cover layer is an insulator (for example, synthetic resin material such as polyimide), configured in a thin film-like (sheet-like) shape, and placed over the base layer such that the wiring layers 10e are sandwiched with the base layer. More specifically, the wiring layers 10e in plurality and in parallel are sandwiched by the base layer and the cover layer, and are covered with the base layer and the cover layer. Therefore, each of the wiring layers 10e is insulated from the other wiring layers 10e and other electrical components (electrical components other than the FPC 10). The base layer and the cover layer are integrated (coupled) by, for example, adhesion or the like. Furthermore, at the end of the FPC 10, a portion of the cover layer or the base layer is removed to expose the wiring layers 10e. A portion at which the wiring layers 10e are exposed at the end of the FPC 10 in a longer direction is then coupled (inserted) to the connector 62. At the portion in which the base layer or the cover layer is removed, there may be a reinforcement layer provided on the opposite side of the wiring layers 10e. The FPC 10 is then bent or bifurcated (not illustrated) as illustrated in FIGS. 3 and 4. The specifications of the wiring layers 10e (for example, the width, shape, thickness, bending form, number of the wiring layers 10e, and shapes of the wiring layers 10e) can be defined appropriately. In the first embodiment, an area of the FPC 10 at which the wiring layers 10e are provided (the base layer, the wiring layers 10e, and the cover layer) is an example of a wiring area 10a.

In the first embodiment, as one example, the FFC 11 comprises a plurality of wiring in parallel (for example, twisted wires, not illustrated) covered with insulating resin (for example, synthetic resin material). As one example, the covering of the FFC 11 is softer than that of the FPC 10. Accordingly, as one example, the FFC 11 is softer than the FPC 10 and easier to warp.

Furthermore, in the first embodiment, as illustrated in FIGS. 3 to 5 as one example, the FPC 10 and the FFC 11 partially overlap with each other in the thickness direction of the housing 3A (the thickness direction of the FPC 10 and the FFC 11, the left-right direction in FIGS. 2 and 5, or a direction perpendicular to the drawing planes of FIGS. 3 and 4). When the FPC 10 and the FFC 11 overlap with each other and an edge 10a1 of the FPC 10 and an edge 11a of the FFC 11 intersect with each other at an acute angle, the edge 10a1 of the FPC 10 and the edge 11a of the FFC 11 rub against each other by external force, inertial force, and others acting on the housing 3A, whereby one or both of them may wear out. With the FPC 10 in the first embodiment illustrated in FIG. 4, the wiring area 10a is bent at roughly a right angle in an L-shape at a bending portion 10d. Now, suppose that a projecting portion 10b is not provided on the FPC 10, an edge of the FPC 10 (lying along an edge 10c of the wiring area 10a, not illustrated) and the edge 11a of the FFC 11 intersect with each other at an acute angle at the bending portion 10d. In this regard, in the first embodiment, as one example, the FPC 10 has the projecting portion 10b (a bulging portion) that projects from the edge 10c of the wiring area 10a towards the outside of the FPC 10 in the width direction (outer side of the curvature) to overlap with the FFC 11. Consequently, in accordance with the first embodiment, as one example, the edge 10a1 of the FPC 10 and the edge 11a of the FFC 11 are likely to be prevented from intersecting with each other at an acute angle.

Furthermore, in the first embodiment, as one example, an edge 10b1 of the projecting portion 10b and the edge 11a of the FFC 11 intersect with each other at roughly a right angle. Accordingly, the surface of the FPC 10 (the surface on the reverse side in the line of sight in FIG. 4) is likely to make contact with the edge 11a of the FFC 11, and thus the wear in the edge 11a of the FFC 11 is likely to be suppressed. Moreover, in the first embodiment, as one example, the edge 10b1 at the tip of the projecting portion 10b is curved. Consequently, in accordance with the first embodiment, as one example, as compared with when the tip of the projecting portion 10b is sharp, the FFC 11 is likely to be prevented from being damaged by the tip of the projecting portion lob. Additionally, in the first embodiment, as one example, the projecting portion 10b is configured by the base layer and the cover layer as insulators (insulating portions). Therefore, in accordance with the first embodiment, as one example, the projecting portion 10b can insulate the wiring layers 10e of the wiring area 10a from the other electrical components (the FFC 11 and electrical components other than the FFC 11).

As in the foregoing, in the first embodiment, as one example, the FPC 10 has the projecting portion 10b that projects from the wiring area 10a and overlaps with (covers) the FFC 11. Consequently, in accordance with the first embodiment, as one example, the edge 10a1 of the FPC 10 and the edge 11a of the FFC 11 are likely to be prevented from contacting with each other. As a consequence, as one example, an inconvenient event based on the contact of the edges 10a1 and 11a is prevented from arising.

Furthermore, in the first embodiment, as one example, the projecting portion 10b is provided at the bending portion 10d of the FPC 10. Consequently, in accordance with the first embodiment, as one example, the edge of the bending portion 10d of the FPC 10 and the edge 11a of the FFC 11 are likely to be prevented from intersecting with each other at an acute angle. Accordingly, as one example, an inconvenient event based on the contact of the edges 10a1 and 11a is likely to be prevented from arising. Moreover, in accordance with the first embodiment, as one example, the FPC 10 becomes harder to bend at the bending portion 10d. In the first embodiment, as one example, a portion of the FPC 10 lies along the FFC 11 and is bent at the bending portion 10d. Accordingly, a portion of the FPC 10 including a portion of the bending portion 10d extends in a direction in which the FPC 10 intersects with the FFC 11. In other words, as one example, the projecting portion 10b is provided at the portion extending in the direction in which the FPC 10 intersects with the FFC 11. Consequently, in accordance with the first embodiment, as one example, the projecting portion 10b is likely to prevent the edges 10a1 and 11a from intersecting with each other at an acute angle.

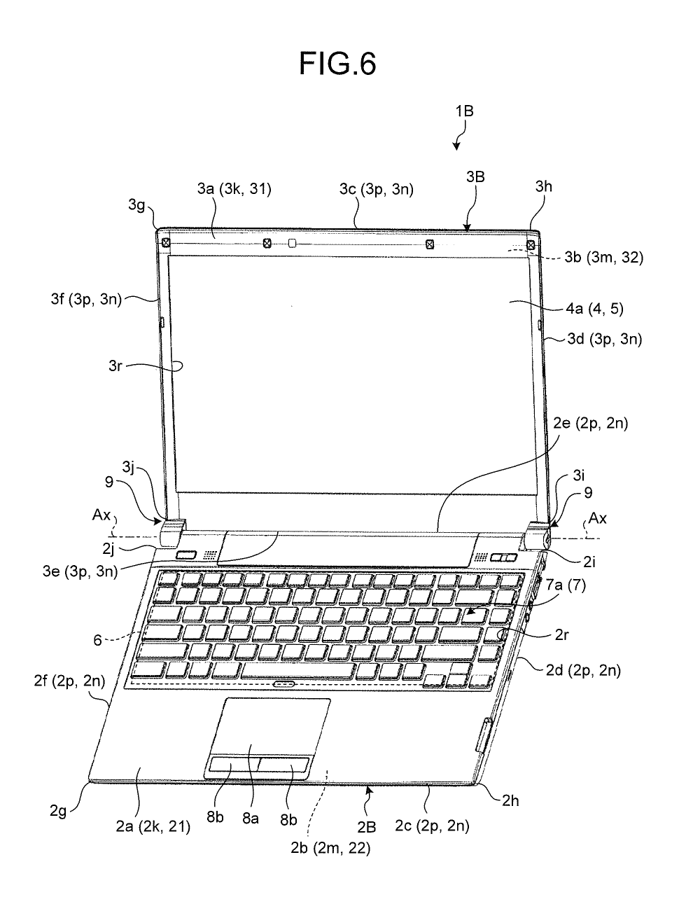

In a second embodiment, as illustrated in FIG. 6 as one example, an electronic device 1B comprises a first housing 3B, and a second housing 2B. Specifically, the first housing 3B (a first portion, or a housing) houses therein at least a portion of the display device 4. On the first housing 3B, the transparent touch panel 5 (a touch sensor, an input operation module, an input receiver, or an input module) can be further provided overlapping the display device 4. The user, for example, can view videos (images) displayed on the display screen 4a of the display device 4 through the touch panel 5.

As illustrated in FIG. 6, the second housing 2B (a second portion, or a housing) houses therein the substrates 6. On the second housing 2B, a keyboard 7 (an input operation module, a first input operation module, an input receiver, or an input module), a pointing device 8a (an input operation module, a second input operation module, an input receiver, and an input module), click buttons 8b (input operation modules, input receivers, or input modules), and such are provided.

The first housing 3B and the second housing 2B are rotatably connected by a hinge mechanism 9 (a hinge, a connector, a coupling portion, a rotatably supporting portion, a connecting mechanism, a coupling mechanism, or a rotatably supporting mechanism). The first housing 3B and the second housing 2B are connected by the hinge mechanism 9 to be rotatable at least between an opened state illustrated in FIG. 6 and a folded state not illustrated. In the second embodiment, as one example, the hinge mechanism 9 connects the first housing 3B and the second housing 2B to be rotatable around a rotation axis Ax.

The display screen 4a of the display device 4 is visible through an opening 3r provided on a surface 3a (an anterior surface, a top surface, a front face, or a face portion) of the first housing 3B. The keyboard 7, the pointing device 8a, the click buttons 8b, and such are exposed on a surface 2a (an anterior surface, a top surface, a front face, or a face portion) of the second housing 2B. In the folded state, the surface 3a of the first housing 3B and the surface 2a of the second housing 2B overlap with each other, and the display screen 4a, the keyboard 7, the pointing device 8a, the click buttons 8b, and others are hidden by the first housing 3B and the second housing 2B. In the opened state, the surface 3a of the first housing 3B and the surface 2a of the second housing 2B are exposed, and the display screen 4a, the keyboard 7, the pointing device 8a, the click buttons 8b, and others are available for use (become visible or operational). There may be a situation where one side of the first housing in a thickness direction is covered with a surface of a touch panel. In this case, the surface of the touch panel is the surface of the first housing. Furthermore, there may be a situation where a display device with a touch panel (not illustrated) is provided on the second housing, in place of the keyboard. Moreover, there may be a situation where one side of the second housing in a thickness direction is covered with a surface of a touch panel. In these cases, the surface of the touch panel is the surface of the second housing.

The first housing 3B, in the second embodiment, as illustrated in FIG. 6 as one example, is configured in a quadrangular shape (in the second embodiment, a rectangular shape as one example) in a frontal view and in aback view. Furthermore, the first housing 3B, in the second embodiment, as one example, is configured in a thin and flat rectangular parallelepiped shape. The first housing 3B comprises the surface 3a and a surface 3b (a rear surface, a lower surface, a back surface, or a surface portion) on the side opposite the surface 3a. Both of the surface 3a and the surface 3b extend (expand) along a direction intersecting a thickness direction of the first housing 3B (in the second embodiment, in an orthogonal direction as one example). The surface 3a and the surface 3b are roughly in parallel with each other. The first housing 3B, as illustrated in FIG. 6, further comprises four end s 3c to 3f (sides, or edges) and four corners 3g to 3j (protruding portions, rounded portions, or ends) in a frontal view. The ends 3c and 3e are examples of longer sides. The ends 3d and 3f are examples of shorter sides.

The first housing 3B further comprises a wall 3k (a portion, a plate, a frame, a front wall, a surface wall, or a top wall) having the surface 3a, and a wall 3m (a portion, a plate, a rear wall, a back wall, or a bottom wall) having the surface 3b. The walls 3k and 3m are in a quadrangular shape (in the second embodiment, a rectangular shape as one example). The first housing 3B further comprises four walls 3n (portions, plates, side walls, end walls, standing walls, or extending portions) having surfaces 3p (side surfaces, or circumferential surfaces) extending between the wall 3k and the wall 3m. On the wall 3k, the opening 3r in a quadrangular shape as one example is provided. Therefore, the wall 3k is in a quadrangular and frame-like shape.

Furthermore, the first housing 3B can be constructed with a plurality of components (segmented bodies) combined. The first housing 3B comprises, in the first embodiment, as one example, a housing member 31 (a front side member, a mask, a mask portion, a cover, a front cover, a cover portion, a portion, or an area) having at least the wall 3k, and a housing member 32 (a back side member, a base, a base portion, a bottom, a bottom portion, a cover, a rear cover, a cover portion, a portion, or an area) having at least the wall 3m. The walls 3n are comprised in at least one of the housing member 31 and the housing member 32 (for example, the housing member 32). Moreover, the first housing 3B can comprise another housing member (an intermediate member, an isolating member, a barrier wall member, a wall member, an intervening member, a covering member, an inner plate, a middle plate, a middle frame, a shield, a portion, or an area, not illustrated) positioned between the housing member 31 and the housing member 32. The first housing 3B can be composed of, for example, metallic or synthetic resin material.

In the second embodiment, as one example, the display device 4 is configured in a quadrangular shape (in the second embodiment, a rectangular shape as one example) in a frontal view. Furthermore, the display device 4 is configured in a rectangular parallelepiped shape being thin and flat in a front-back direction. The display device 4, for example, is a liquid crystal display (LCD) or an organic electro-luminescent display (OELD).

In the second embodiment, as one example, the touch panel 5 is configured to be transparent in a relatively thin quadrangular shape. An operator (for example, a user) can execute input process by performing an operation of touching, pressing, or rubbing the touch panel 5 with a finger or a component (for example, a stylus, not illustrated), or moving the finger or the stylus near the touch panel 5. The light emitted from the display screen 4a of the display device 4 passes (transmits) through the touch panel 5 and goes out ahead (outside) of the first housing 3B through the opening 3r of the wall 3k.

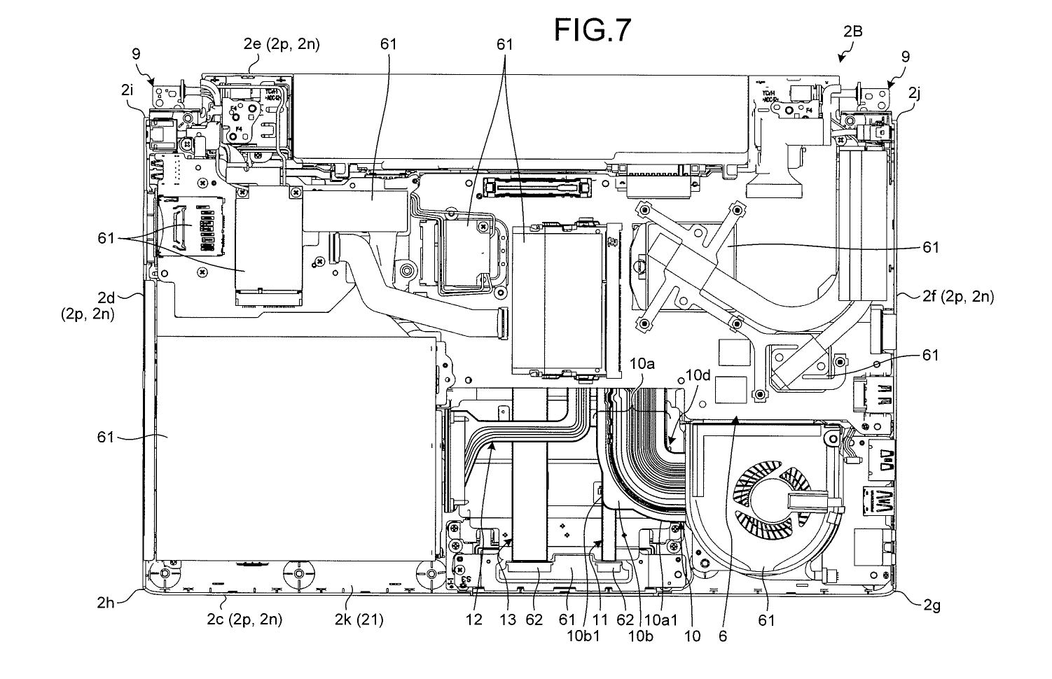

The second housing 2B, in the second embodiment, as illustrated in FIGS. 6 and 7 as one example, is configured in a quadrangular shape (in the second embodiment, a rectangular shape as one example) in a frontal view and in a back view. The second housing 2B, in the second embodiment, as one example, is configured in a thin and flat rectangular parallelepiped shape. The second housing 2B comprises the surface 2a and a surface 2b (a rear surface, a lower surface, a back surface, or a surface portion) on the side opposite the surface 2a. Both of the surface 2a and the surface 2b extend (expand) along a direction intersecting a thickness direction of the second housing 2B (in the second embodiment, in an orthogonal direction as one example). The surface 2a and the surface 2b are roughly in parallel with each other. The second housing 2B further comprises four ends 2c to 2f (sides, or edges) and four corners 2g to 2j (protruding portions, rounded portions, or ends) in a frontal view with respect to the surface 2a. The ends 2c and 2e are examples of longer sides. The ends 2d and 2f are example of shorter sides.

The second housing 2B further comprises a wall 2k (a portion, a plate, a frame, a front wall, a surface wall, or a top wall) having the surface 2a, and a wall 2m (a portion, a plate, a rear wall, a back wall, or a bottom wall) having the surface 2b. The walls 2k and 2m are in a quadrangular shape (in the second embodiment, a rectangular shape as one example). The second housing 2B further comprises four walls 2n (portions, plates, side walls, end walls, standing walls, or extending portions) having surfaces 2p (side surfaces, or circumferential surfaces) extending between the wall 2k and the wall 2m. On the wall 2k, an opening 2r in a quadrangular shape as one example is provided. Accordingly, the wall 2k is in a quadrangular and frame-like shape.

Furthermore, the second housing 2B, as one example, can be configured with a plurality of components (segmented bodies) combined. The second housing 2B, in the second embodiment, as one example, comprises a housing member 21 (a front side member, a mask, a mask portion, a cover, a front cover, a cover portion, a portion, or an area) having at least the wall 2k, and a housing member 22 (a back side member, a base, a base portion, a bottom, a bottom portion, a cover, a rear cover, a cover portion, a portion, or an area) having at least the wall 2m. The walls 2n are comprised in at least one of the housing member 21 and the housing member 22 (for example, the housing member 22). Moreover, the second housing 2B can comprise another housing member (an intermediate member, an isolating member, a barrier wall member, a wall member, an intervening member, a covering member, an inner plate, a middle plate, a middle frame, a shield, a portion, or an area, not illustrated) positioned between the housing member 21 and the housing member 22. The second housing 2B can be composed of, for example, metallic or synthetic resin material.

In the second embodiment, as one example, an operation surface 7a (a surface, or a top surface) of the keyboard 7 is exposed towards the front (outside) of the second housing 2B through the opening 2r. On the surface 2a, the keyboard 7 is positioned close to the end 2e side, and the pointing device 8a and the click buttons 8b are arranged close to the end 2c side that is on the side opposite to the end 2e. The end 2e is positioned on the back side in a depth direction (a front-back direction), and the end 2c is positioned on the near side.

In the second embodiment, as illustrated in FIG. 6 as one example, the second housing 2B houses one or more substrates 6 (a circuit board, a control board, a main board, or electrical components) on the rear side of the keyboard 7 (a reverse side, a back side, the wall 2m side, or the side opposite the operation surface 7a). The substrates 6 are provided in parallel with the keyboard 7. The substrates 6 are provided in a condition to be away from the walls 2k, 2m, 2n, and others, in other words, in a condition where spaces (gaps) are formed with the walls 2k, 2m, 2n, and others.

In the second embodiment, as one example, on the substrates 6, a plurality of components (not illustrated) such as a central processing unit (CPU), a graphics controller, power supply circuit components, a platform controller hub (PCH), a memory slot connector, an LCD connector, an input/output (I/O) connector, a power coil, elements, and connectors can be mounted. The control circuit can comprise, for example, a video signal processing circuit, a tuner, a High-Definition Multimedia Interface (HDMI) signal processor, an audio video (A/V) input terminal, a remote control signal receiver, a controller, a selector, an on-screen display interface, a storage module (for example, a read only memory (ROM), a random access memory (RAM), a hard disk drive (HDD), and a solid state drive (SSD)), and an audio signal processing circuit. The control circuit controls such as the output of videos (such as movies and still pictures) on the display screen 4a of the display device 4, the output of audio from a speaker (not illustrated), and light emission of a light emitting diode (LED, not illustrated). The display device 4, the speaker, and the LED are examples of output modules.

In the second embodiment, as illustrated in FIG. 7 as one example, the second housing 2B houses therein, other than the substrates 6, various electrical components 61. In the second embodiment, as one example, the second housing 2B further houses therein the FPCs 10 and 12, and the FFCs 11 and 13 (electrical components, cables, flat cables, or flexible cables). In the second embodiment, as one example, the FFC 13 and the FPC 12 overlap with each other in a roughly orthogonal state. Meanwhile, the FPC 10 is, similarly to that in the first embodiment, bent at the bending portion 10d at roughly a right angle. On the outer side of the curvature of the bending portion 10d, the projecting portion 10b is provided. The projecting portion 10b overlaps with the FFC 11. In other words, the FPC 10 partially overlaps with the FFC 11 similarly to that in the first embodiment. Consequently, the second embodiment can yield similar results (effects) based on a similar structure to that in the first embodiment.

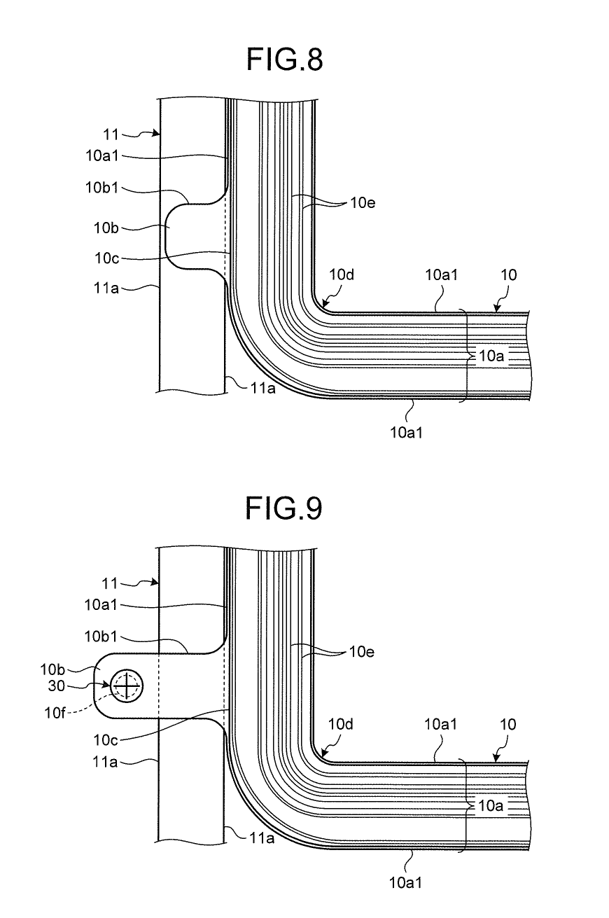

In a first modification of the above-described embodiments, as illustrated in FIG. 8 as one example, the FPC 10 and the FFC 11 are arranged to be partially adjacent to and in juxtaposition with each other (in the first modification, roughly in parallel as one example). The FPC 10 has the projecting portion 10b. The projecting portion 10b projects from the edge 10a1 of the wiring area 10a of the FPC 10 in the width direction of the FPC 10 (the wiring area 10a). The projecting portion 10b overlaps with the FFC 11 and covers the FFC 11. The projecting portion 10b projects along the width direction of the FFC 11 and extends partway through the width of the FFC 11. Therefore, the first modification can yield similar results (effects) based on a similar structure to those in the above-described embodiments. The FPC 10 and the FFC 11 in the first modification can be used in a variety of electronic devices.

In a second modification of the above-described embodiments, as illustrated in FIG. 9 as one example, the FPC 10 and the FFC 11 are arranged to be partially adjacent to and in juxtaposition with each other (in the second modification, roughly in parallel as one example). The FPC 10 has the projecting portion 10b. The projecting portion 10b projects from the edge 10a1 of the wiring area 10a of the FPC 10 in the width direction of the FPC 10 (the wiring area 10a). The projecting portion 10b overlaps with the FFC 11 and covers the FFC 11. The projecting portion 10b projects along the width direction of the FFC 11, and straddles the FFC 11 to extend up to the side opposite the wiring area 10a. In the area on the opposite side, an opening 10f (as one example, a through hole) is provided. A coupling tool 30 passing through the opening 10f being fixed (coupled) to the housing 3A or the second housing 2B, or to a component fixed to the housing 3A or the second housing 2B (as one example, the substrate 6) fixes (couples) the projecting portion 10b and eventually the FPC 10 to the housing 3A or the second housing 2B, or to the component fixed to the housing 3A or the second housing 2B, respectively. In other words, in the second modification, the opening 10f of the projecting portion 10b and the surrounding portion thereof are examples of a coupling portion. Accordingly, the second modification can yield similar results (effects) based on a similar structure to those in the above-described embodiments and the modification. Furthermore, in the second modification, the projecting portion 10b straddles the FFC 11. Consequently, in accordance with the second modification, as one example, the movement of the FFC 11 is more likely to be suppressed by the projecting portion 10i. Moreover, in the second modification, the projecting portion 10b is fixed (coupled) to the housing 3A or the second housing 2B, or to the component fixed to the housing 3A or the second housing 2B. Consequently, in accordance with the second modification, as one example, the movement of the FFC 11 is furthermore likely to be suppressed by the projecting portion 10b. The FPC 10 and the FFC 11 in the second modification can be used in a variety of electronic devices.

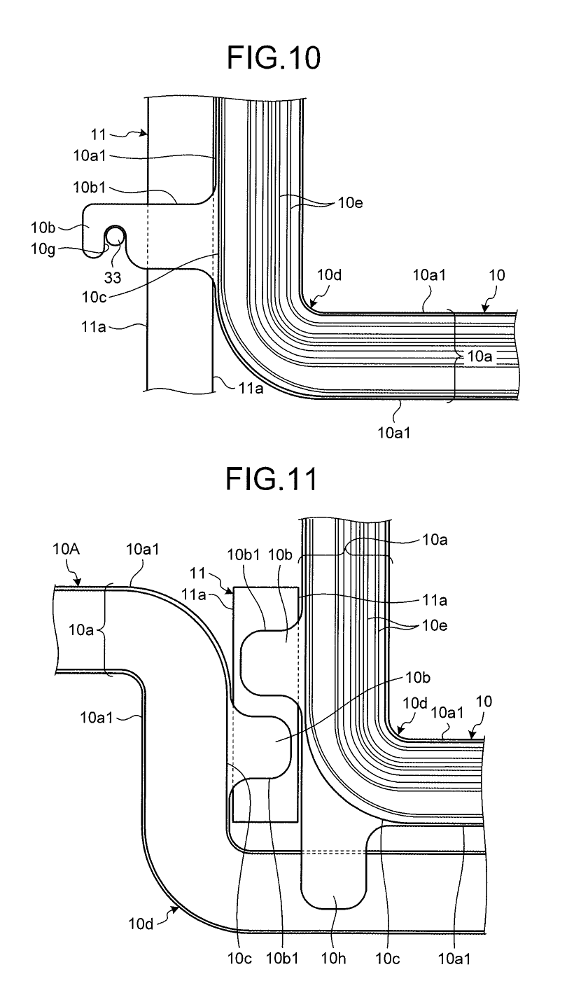

In a third modification of the above-described embodiments, as it becomes apparent when FIG. 10 is compared with FIG. 9, the structure of the projecting portion 10b is different from that in the second modification. More specifically, in the third modification, provided on the projecting portion 10b is not the opening 10f in the second modification but an opening 10g (as one example, a cutout). In the third modification, a projecting portion 33 (a component) formed on the housing 3A or the second housing 2B, or the projecting portion 33 fixed to the housing 3A or the second housing 2B is inserted in the opening 10g, and the projecting portion 10b is hooked (supported) on the projecting portion 33 . In other words, in the third modification, the opening 10g of the projecting portion 10b and the surrounding portion thereof are examples of a coupling portion. Consequently, the third modification can yield similar results (effects) based on a similar structure to those in the above-described embodiments and the modifications. Furthermore, in accordance with the third modification, as one example, because the coupling tool 30 is not provided as compared with the second modification, the number of components is more likely to be reduced and the time and effort required for assembling are more likely to be reduced. The FPC 10 and the FFC 11 in the third modification can be used in a variety of electronic devices.

In a fourth modification of the above-described embodiments, as illustrated in FIG. 11 as one example, the FPC 10, an FPC 10A, and FFC 11 are arranged to be partially adjacent to and in juxtaposition with one another (in the fourth modification, roughly in parallel as one example). Each of the FPCs 10 and 10A has the projecting portion 10b. Each of the projecting portions 10b projects from the respective edges 10a1 of the wiring areas 10a of the FPCs 10 and 10A in the width directions of the respective FPCs 10 and 10A (the wiring areas 10a). Each of the projecting portions 10b overlaps with the FFC 11 and covers the FFC 11. Each projecting portion 10b projects along the width direction of the FFC 11 and extends partway through the width of the FFC 11. Each of the projecting portions 10b overlaps with (covers) the FFC 11 at a portion different from each other. In the fourth modification, the FPC 10 further has a projecting portion 10h. The projecting portion 10h projects from the edge 10c of the wiring area 10a at the bending portion 10d of the FPC 10 in the width direction of the bending portion 10d (outer side of the curvature). The projecting portion 10h further projects in the width direction of the FPC 10A and extends partway through the FPC 10A. The projecting portion 10h overlaps with (covers) the FPC 10A. Therefore, the fourth modification can yield similar results (effects) based on a similar structure to those in the above-described embodiments and the modifications. Furthermore, in the fourth modification, the projecting portions 10b overlap with the FFC 11. Consequently, in accordance with the fourth modification, as one example, the movement of the FFC 11 is further more likely to be suppressed. Moreover, the projecting portion 10h of the FPC 10 overlaps with the FPC 10A. As a consequence, in accordance with the fourth modification, as one example, the movement of the FPC 10A is likely to be suppressed, and eventually the movement of the FFC 11 is furthermore likely to be suppressed.

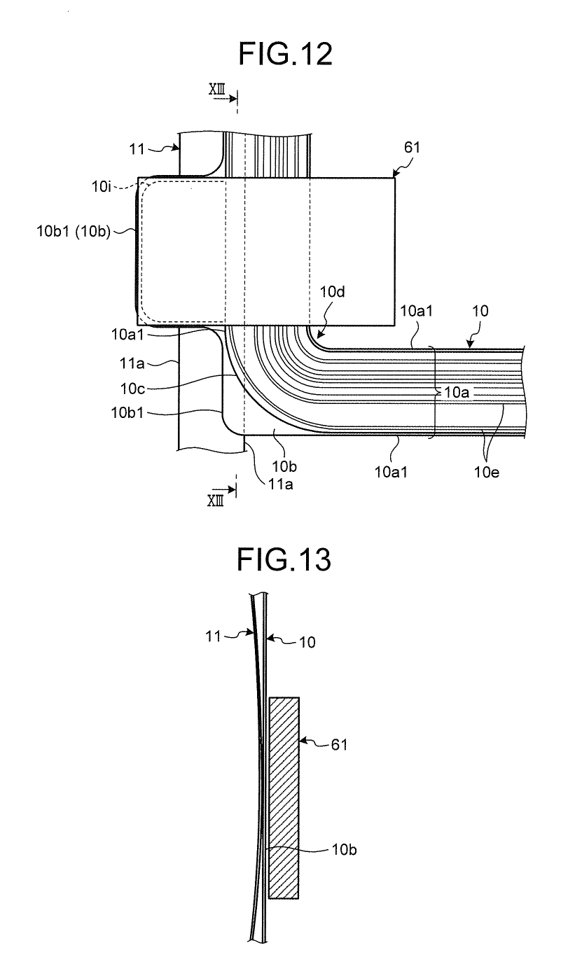

In a fifth modification of the above-described embodiments, as illustrated in FIGS. 12 and 13 as one example, the FPC 10 partially overlaps with (covers) the FFC 11. The FPC 10 further has the projecting portion 10b. The projecting portion 10b projects from the edge 10a1 of the wiring area 10a of the FPC 10 in the width direction of the FPC 10 (the wiring area 10a). The projecting portion 10b overlaps with the FFC 11 and covers the FFC 11. The projecting portion 10b projects along the width direction of the FFC 11, and straddles the FFC 11 to extend up to the side opposite the wiring area 10a. Furthermore, in the fifth modification, an electrical component 61 is provided to overlap with the FPC 10 and the FFC 11. The electrical component 61 is housed in the housing 3A or the second housing 2B, and is, for example, an SSD or a communication module. The projecting portion 10b is provided to be sandwiched by the electrical component 61 and the FFC 11. More specifically, the projecting portion 10b lies between the electrical component 61 and the FFC 11. In the projecting portion 10b, a conductor layer 10i (a conductive layer, a conductor, a shield layer, or a shield member) lies between the base layer and the cover layer (neither are depicted) as insulators (insulating portions). The conductor layer 10i can serve as an electromagnetic shield between the electrical component 61 and the FFC 11. The conductor layer 10i can be electrically connected to the wiring layer 10e of a ground potential in the wiring area 10a. This facilitates the ground potential to be used commonly, and the potential of the conductor layer 10i is likely to be prevented from floating. Therefore, the fifth modification can yield similar results (effects) based on a similar structure to those in the above-described embodiments and the modifications. Furthermore, in accordance with the fifth modification, the projecting portion 10b can be used as an electromagnetic shield. Consequently, noise contamination to electrical signals used for the FPC 10, the FFC 11, and the electrical component 61, and mutual interference in electrical signals and in electromagnetic waves are likely to be suppressed. The structure in the fifth modification can be used in a variety of electronic devices.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions. Furthermore, the structures and shapes in the embodiments described above can be implemented while partially replaced with one another. The specifications (such as the structure, type, direction, shape, size, length, width, thickness, height, number of pieces, arrangement, position, and material) of each of the structures and shapes can be implemented with appropriate changes. For example, a projecting portion can be provided not on an FPC but on an FFC using the FFC, or an FPC can be used instead of the FFC. Furthermore, the projecting portion of the FPC or the FFC can be constructed to overlap with (to cover) an electrical component other than a cable. Moreover, the object covered by the projecting portion of a flat cable (FPC) may be a cable or another electrical component, besides the FPC and the FFC.

What is claimed is:

1. A television receiver comprising:
a housing;
a display device comprising a display screen, at least a portion of the display device being housed in the housing;
a cable housed in the housing; and
a flexible printed wiring board housed in the housing, at least a portion of the flexible printed wiring board being provided to position along or to overlap with the cable, the flexible printed wiring board comprising a wiring area and a projecting portion configured to project from the wiring area and to overlap with the cable.

2. The television receiver of claim 1, wherein the projecting portion comprises an insulator configured to insulate the wiring area from an electrical component.

3. The television receiver of claim 1, wherein the projecting portion comprises a conductor layer.

4. The television receiver of claim 2, further comprising an electrical component positioned to sandwich the projecting portion with the cable.

5. The television receiver of claim 1, wherein the projecting portion is provided at a bending portion of the flexible printed wiring board.

6. The television receiver of claim 1, wherein
the wiring area comprises a portion extended in a direction intersecting the cable, and
the projecting portion is configured to project from the portion extended in the direction intersecting the cable.

7. The television receiver of claim 1, wherein the projecting portion comprises a curved edge.

8. The television receiver of claim 1, wherein an edge of the projecting portion and an edge of the cable are substantially orthogonal to each other.

9. The television receiver of claim 1, further comprising a coupling portion provided on a side of the projecting portion opposite the wiring area with respect to the cable, the coupling portion being configured to be coupled to the housing or a component in the housing.

10. An electronic device comprising:
a housing;
a cable housed in the housing; and
a flexible printed wiring board housed in the housing, and provided with a projecting portion configured to cover the cable.

11. An electronic device comprising:
a housing;
an electrical component housed in the housing; and
a flat cable housed in the housing, and provided with a projecting portion configured to cover the electrical component.
